(19) United States
(12) Patent Application Publication
(10) Pub. No.: US 2007/0018176 A1
(43) Pub. Date: Jan. 25, 2007

(54) IMAGE DISPLAY DEVICE AND METHOD OF MANUFACTURING THE SAME

(76) Inventor: Daiji Hirosawa, Fukaya-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/536,258

(22) Filed: Sep. 28, 2006

Related U.S. Application Data
(63) Continuation of application No. PCT/JP05/05763, filed on Mar. 28, 2005.

(30) Foreign Application Priority Data
Mar. 29, 2004 (JP) 2004-096129

(51) Int. Cl. H01L 33/00

(52) U.S. Cl. 257/89

(57) ABSTRACT

An image display device includes an envelope having a first substrate and a second substrate located opposite the first substrate across a gap and a plurality of pixels provided in the envelope. A plurality of columnar spacers which support an atmospheric load acting on the first and second substrates are set up between the first substrate and the second substrate in the envelope. Each spacer is formed of a dielectric material and has a plurality of step portions arranged in a setup direction of the spacer. Coating films which are formed intermittently and divided electrically from one another are formed on a surface of the spacer.

### CROSS-REFERENCE TO RELATED APPLICATIONS

This is a Continuation Application of PCT Application No. PCT/JP2005/005763, filed Mar. 28, 2005, which was published under PCT Article 21(2) in Japanese.

This application is based upon and claims the benefit of priority from prior Japanese Patent Application No. 2004-096129, filed Mar. 29, 2004, the entire contents of which are incorporated herein by reference.

### BACKGROUND OF THE INVENTION

1. Field of the Invention

This invention relates to an image display device, provided with substrates opposed to each other and a spacer structure located between the substrates, and a manufacturing method therefore.

2. Description of the Related Art

In recent years, various flat image display devices have been noticed as a next generation of lightweight, thin display devices to replace cathode-ray tubes (CRTs). For example, a surface-conduction electron emission device (SED) has been developed as a kind of a field emission device (FED) that serves as a flat display device.

The SED comprises a first substrate and a second substrate that are opposed to each other across a predetermined gap. These substrates have their respective peripheral portions joined together by a rectangular sidewall, thereby constituting a vacuum envelope. Three-color phosphor layers are formed on the inner surface of the first substrate. Arranged on the inner surface of the second substrate are a large number of electron emitting elements, which correspond individually to pixels and serve as electron emission sources that excite the phosphors. Each electron emitting element is formed of an electron emitting portion, a pair of element electrodes that apply voltage to the electron emitting portion, etc.

For the SED, it is important to maintain a high degree of vacuum in a space between the first substrate and a second substrate, that is, in the vacuum envelope. If the degree of vacuum is low, the life performance of the electron emitting elements, and therefore, the life performance of the device lower inevitably. In order to support an atmospheric load that acts between the first substrate and the second substrate and maintain the gap between the substrates, as described in Jpn. Pat. Appln. KOKAI Publication No. 2001-272926, for example, a large number of plate-like or columnar spacers are located between the two substrates. In displaying an image on the SED described above, an anode voltage is applied to the phosphor layers, and the electron beams emitted from the electron emitting elements are accelerated by the anode voltage and collided with the phosphor layers. Thereupon, the phosphors glow and display the image. In order to obtain practical display characteristics, it is necessary to use phosphors similar to those of conventional cathode ray tubes and set the anode voltage to several kV or more, and preferably, to 5 kV or more.

If electrons with high acceleration voltage collide with a phosphor screen in the SED constructed in this manner, secondary electrons and reflected electrons are generated on the phosphor screen. If the space between the first substrate and the second substrate is narrow, the secondary electrons and reflected electrons generated on the phosphor screen collide with the spacers arranged between the substrates, whereupon the spacers are electrified. Thus, electric discharge easily occurs near the spacers. In order to prevent electrification of the spacers, a coating film, such as a metal film or metal oxide film, may possibly be formed on the spacer surface. If the coating film is formed on the entire spacer film, a current leakage through the spacers is caused, and it is hard to apply the anode voltage to the phosphor layers.

The above-described SED includes a getter film that is formed on the inner surface of the vacuum envelope. When this getter film is formed, however, a getter film may possibly be also formed on the spacer surface. If the getter film is formed on the entire spacer surface, a current leakage is caused, and it is hard to apply the anode voltage to the phosphor layers, as in the aforesaid case.

### BRIEF SUMMARY OF THE INVENTION

This invention has been made in consideration of these circumstances, and its object is to provide an image display device with improved reliability, in which electric discharge attributable to electrification of spacers can be suppressed.

According to an aspect of the invention, there is provided an image display device comprising: an envelope having a first substrate and a second substrate located opposite the first substrate across a gap; a plurality of pixels provided in the envelope; and a plurality of columnar spacers which are individually formed of a dielectric material, are arranged between the first substrate and the second substrate in the envelope, and support an atmospheric load acting on the first and second substrates, each of the spacers having a plurality of step portions arranged in a setup direction thereof and coating films which are formed intermittently on a surface of the spacer and divided electrically from one another.

According to another aspect of the invention, there is provided a method of manufacturing an image display device which comprises an envelope having a first substrate and a second substrate located opposite the first substrate across a gap, a plurality of pixels provided in the envelope, and a plurality of columnar spacers which are individually formed of a dielectric material, are set up between the first substrate and the second substrate in the envelope, and support an atmospheric load acting on the first and second substrates, each of the spacers having a plurality of step portions arranged in a setup direction thereof and coating films are formed intermittently on a surface of the spacer and divided electrically from one another, the method comprising:

forming a plurality of columnar spacers each having a plurality of step portions arranged in the setup direction, using the dielectric material; and

scattering a film material toward the spacers in a vacuum atmosphere to form the coating films on the spacer surface and, at the same time, regulating the direction of scattering of the film material in one predetermined direction to control a film distribution by a guide member, thereby forming the coating films formed intermittently on the spacer surface and divided electrically from one another.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view showing an SED according to a first embodiment of this invention;

FIG. 2 is a perspective view of the SED, broken away along line II-II of FIG. 1;

FIG. 3 is a sectional view enlargedly showing the SED;

FIG. 4 is a perspective view enlargedly showing a part of a spacer structure of the SED;

FIG. 5 is a sectional view showing a supporting substrate and a molding die used for the manufacture of the spacer structure;

FIG. 6 is a sectional view showing a state in which the molding die and the supporting substrate are in close contact with each other;

FIG. 7 is a sectional view showing a state in which the molding die is released;

FIG. 8 is a sectional view showing a film forming apparatus used for the manufacture of the SED;

FIG. 9 is a perspective view showing a grid in the film forming apparatus;

FIG. 10 is a sectional view showing an SED according to a second embodiment of this invention; and

FIG. 11 is a sectional view showing an SED according to a third embodiment of this invention.

### DETAILED DESCRIPTION OF THE INVENTION

An embodiment in which this invention is applied to an SED as a flat image display device will now be described in detail with reference to the drawings.

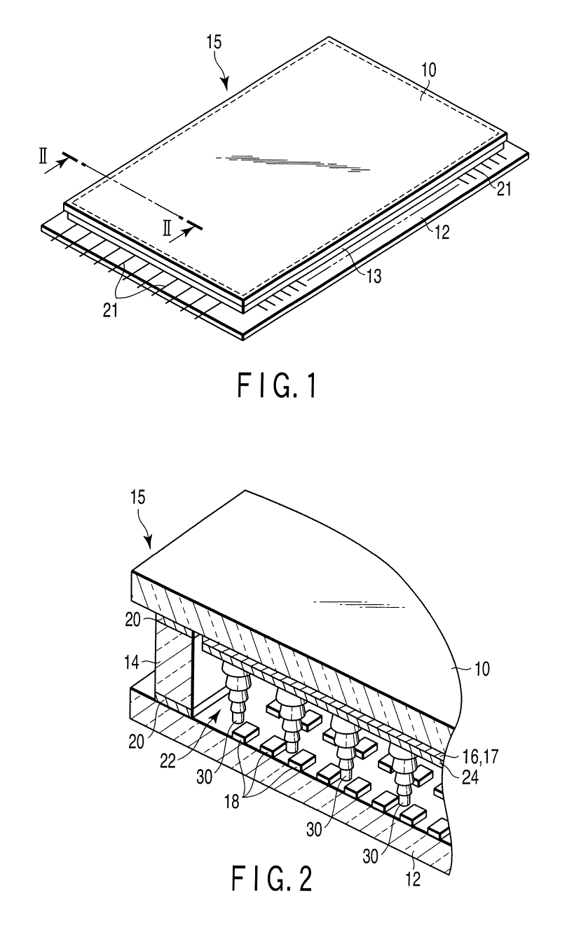

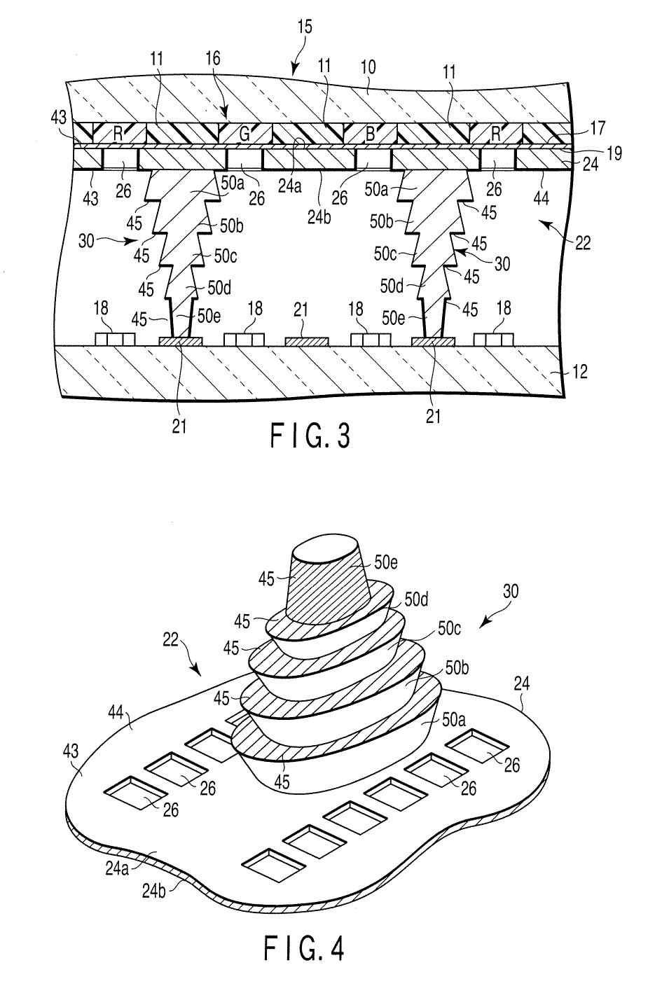

As shown in FIGS. 1 to 3, the SED comprises a first substrate 10 and a second substrate 12, which are formed of a rectangular glass plate each. These substrates are located opposite each other with a gap of about 1.0 to 2.0 mm between them. The first substrate 10 and the second substrate 12 have their respective peripheral edge portions joined together by a sidewall 14 of glass in the form of a rectangular frame, thereby forming a flat vacuum envelope 15 of which the inside is kept vacuum. The sidewall 14 that functions as a joint member is sealed to the peripheral edge portion of the first substrate 10 and the peripheral edge portion of the second substrate 12 with a sealant 20 of, for example, low-melting-point glass or low-melting-point metal, whereby these substrates are joined together.

A phosphor screen 16 that functions as a fluorescent screen is formed on the inner surface of the first substrate 10. The phosphor screen 16 is composed of phosphor layers R, G and B, which glow red, green, and blue, respectively, and light shielding layers 11 arranged side by side. These phosphor layers are stripe-shaped, dot-shaped, or rectangular. A metal back 17 of aluminum or the like and a getter film 19 are successively formed on the phosphor screen 16.

Provided on the inner surface of the second substrate 12 are a large number of surface-conduction electron emitting elements 18, which individually emit electron beams as electron sources for exciting the phosphor layers R, G and B of the phosphor screen 16. These electron emitting elements 18 are arranged in a plurality of columns and a plurality of rows and form pixels in conjunction with their corresponding pixels. Each electron emitting element 18 is formed of an electron emitting portion (not shown), a pair of element electrodes that apply voltage to the electron emitting portion, etc. A large number of wires 21 for supplying potential to the electron emitting elements 18 are provided in a matrix on the inner surface of the second substrate 12, and their respective end portions are led out of the vacuum envelope 15.

A spacer structure 22 is located between the first substrate 10 and the second substrate 12. The spacer structure 22 includes a supporting substrate 24, formed of a rectangular metal plate, and a large number of columnar spacers 30 set up integrally on one surface of the supporting substrate. The supporting substrate 24 has a first surface 24a opposed to the inner surface of the first substrate 10 and a second surface 24b opposed to the inner surface of the second substrate 12, and is located parallel to these substrates. A large number of electron beam apertures 26 are formed in the supporting substrate 24 by etching or the like. The electron beam apertures 26 are arrayed opposite the electron emitting elements 18, individually, and are permeated by the electron beams emitted from the electron emitting elements.

The first and second surfaces 24a and 24b of the supporting substrate 24 and the respective inner wall surfaces of the electron beam apertures 26 are covered by a high-resistance film 43 as a dielectric layer formed of a dielectric substance that consists mainly of glass or ceramic, such as Li-based alkali borosilicate glass. The supporting substrate 24 is provided in a manner such that its first surface 24a is in surface contact with the inner surface of the first substrate 10 with a getter film 19, a metal back 17, and a phosphor screen 16 between them. The electron beam apertures 26 in the supporting substrate 24 individually face the phosphor layers R, G and B of the phosphor screen 16 and the electron emitting elements 18 on the second substrate 12. Thus, the electron emitting elements 18 face their corresponding phosphor layers through the electron beam apertures 26. Formed on the second surface 24b of the supporting substrate 24 is a coating film 44 having a desired thickness and formed of a metal oxide, such as chromium oxide, copper oxide, or iron oxide that contains a material whose secondary electron emission coefficient ranges from 0.4 to 2.0.

A plurality of spacers 30 are set up integrally on the second surface 24b of the supporting substrate 24. Respective extended ends of the spacers 30 abut against the inner surface of the second substrate 12 or, in this case, wires 21 that are provided on the inner surface of the second substrate 12. Each spacer 30 is tapered as a whole so that its diameter is reduced from the side of the supporting substrate 24 toward its extended end.

Each spacer 30 has a plurality of step portions that are laminated from its proximal end on the side of the supporting substrate 24 toward the extended end, and is formed as a spacer having a rugged surface. In the present embodiment, each spacer 30 has five step portions 50a, 50b, 50c, 50d and 50d, first, second, third, fourth, and fifth, and is formed having a height of, for example, 1.4 mm. The adjacent step portions of the spacer 30 are formed so that the step portions on the proximal end side of the spacer are larger in diameter than the step portions on the distal end side of the spacer. The cross section of each step portion is elliptic, for example.

The first to fourth step portions 50a, 50b, 50c and 50d of the spacer 30 are tapered so that their respective diameters increase from the proximal end side of the spacer toward the distal end side. The proximal-end-side diameter of a distal-end-side step portion, out of each two adjacent step portions, is smaller than the distal-end-side diameter of a proximal-end-side step portion. Each of the first to fourth step portions 50a, 50b, 50c and 50d has an annular opposite surface that faces the second substrate 12 in substantially parallel relation. The fifth step portion 50d that is situated at the distal end of each spacer 30 is tapered from its proximal end side toward the distal end side. The first to fifth step portions 50a, 50b, 50c, 50d and 50e have their respective outer circumferential surfaces that are inclined with respect to the setup direction of the spacer, that is, to a direction perpendicular to the supporting substrate 24.

In the spacer 30 thus having a plurality of step portions, coating films 45 of a metal oxide, such as chromium oxide, copper oxide, or iron oxide that contains a material whose secondary electron emission coefficient ranges from 0.4 to 2.0, are formed to a desired thickness on the surface of the fifth step portion 50e at the distal end and the respective distal-end-side surfaces of the other step portions or, in this case, the respective opposite surfaces of the step portions. For ease of understanding, the coating films 45 are hatched in FIG. 4. The coating films 45 are not formed on the respective outer circumferential surfaces of the first to fourth step portions 50a, 50b, 50c and 50d. Thus, the coating films 45 that are formed on the surface of the spacer 30 are formed intermittently in the extending direction of the spacer and divided electrically from one another.

In the spacer structure 22 constructed in this manner, the supporting substrate 24 is in surface contact with the first substrate 10, and the extended ends of the spacers 30 abut against the inner surface of the second substrate 12, thereby supporting an atmospheric load that acts on these substrates and keeping the space between the substrates at a predetermined value.

The SED comprises voltage supply portions (not shown) that apply voltages to the supporting substrate 24 and the metal back 17 of the first substrate 10. The voltage supply portions are connected to the supporting substrate 24 and the metal back 17, individually. In displaying an image on the SED, an anode voltage is applied to the phosphor screen 16 and the metal back 17, and electron beams emitted from the electron emitting elements 18 are accelerated by the anode voltage and collided with the phosphor screen 16. Thereupon, the phosphor layers of the phosphor screen 16 are excited to luminescence and display the image.

The following is a description of a manufacturing method for the SED constructed in this manner. A manufacturing method for the spacer structure 22 will be described first.

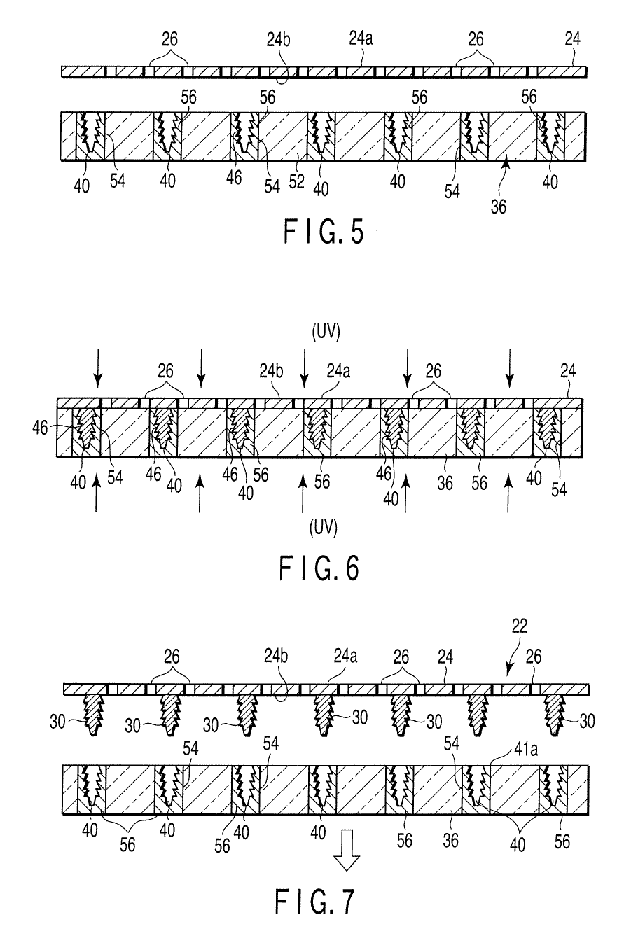

As shown in FIG. 5, the supporting substrate 24 of a predetermined size and a molding die 36, which is in the form of a rectangular plate having substantially the same size as the supporting substrate, are prepared first. After a metal plate of Fe-50% Ni with a plate thickness of 0.15 m is degreased, washed, and dried, in this case, the electron beam apertures 26 are formed by etching, whereupon the supporting substrate 24 is formed. After the entire supporting substrate 24 is oxidized, moreover, a dielectric film is formed on the surface of the supporting substrate including the respective inner surfaces of the electron beam apertures 26. Further, a coating solution that consists mainly of glass is spread on the dielectric film, dried, and then fired, whereupon the high-resistance film 43 is formed.

The molding die 36 comprises a mold body 52 of stainless steel or polyethylene terephthalate in the form of a rectangular plate, and this mold body is formed having a large number of through holes 54 in positions corresponding to the spacers 30, individually. Each through hole 54 has a diameter larger than that of a spacer forming hole. Each through hole 54 is provided with a hole forming portion 56 of, e.g., silicone as an ultraviolet transmitting material that is elastically deformable. This hole forming portion 56 is formed having a bottomed spacer forming hole 40 that is shaped corresponding to the spacer 30. Thus, the spacer forming hole 40 is surrounded by silicone. The elastically deformable ultraviolet transmitting material that is used for the hole forming portion is not limited to silicone, but polycarbonate, acrylic resin, etc. may be also used for the material.

In fabricating a spacer structure using the molding die 36 constructed in this manner, the spacer forming holes 40 of the molding die 36 are filled with a spacer forming material 46. A glass paste that contains at least an ultraviolet-curing binder (organic component) and a glass filler is used as the spacer forming material 46. The specific gravity and viscosity of the glass paste are selected as required.

Subsequently, the molding die 36 is positioned with respect to the supporting substrate 24 and adhered to the second surface 24b of the supporting substrate 24 so that the spacer forming holes 40 filled with the spacer forming material 46 are situated between the electron beam apertures 26, as shown in FIG. 6. In this state, ultraviolet (UV) rays are applied to the loaded spacer forming material 46 from the outer surface side of the molding die 36 using, e.g., ultraviolet lamps, whereby the spacer forming material is UV-cured. As this is done, the spacer forming holes 40 that are loaded with the spacer forming material 46 are surrounded by the hole forming portions 56 that are formed of silicone as an ultraviolet transmitting material. Accordingly, the ultraviolet rays are applied to the spacer forming material 46 directly or through the hole forming portions 56. Thus, the loaded spacer forming material 46 can be securely cured to its inner part.

As shown in FIG. 7, thereafter, the molding die 36 is released from the supporting substrate 24 so that the cured spacer forming material 46 is left on the supporting substrate 24. The cured spacer forming material 46, that is, each spacer 30, is formed having the first to fifth step portions 50a, 50b, 50c, 50d and 50e shaped like irregularities. The hole forming portions 56 that define the spacer forming holes 40 are formed of silicon that is elastically deformable. Thus, the hole forming portions 56 are elastically deformed along the irregularities of the spacers 30 when the molding die 36 is released. If the spacers 30 are formed having irregularities including a plurality of step portions, therefore, the molding die 36 can be easily released without damaging these spacers.

Then, the supporting substrate 24 with the spacer forming material 46 thereon is heat-treated in a heating furnace so that the binder is evaporated from the spacer forming material, and the spacer forming material is then regularly fired at about 500 to 550° C. for 30 minutes to 1 hour. Thus, the spacer structure 22 is obtained having the spacers 30 built-in on the supporting substrate 24.

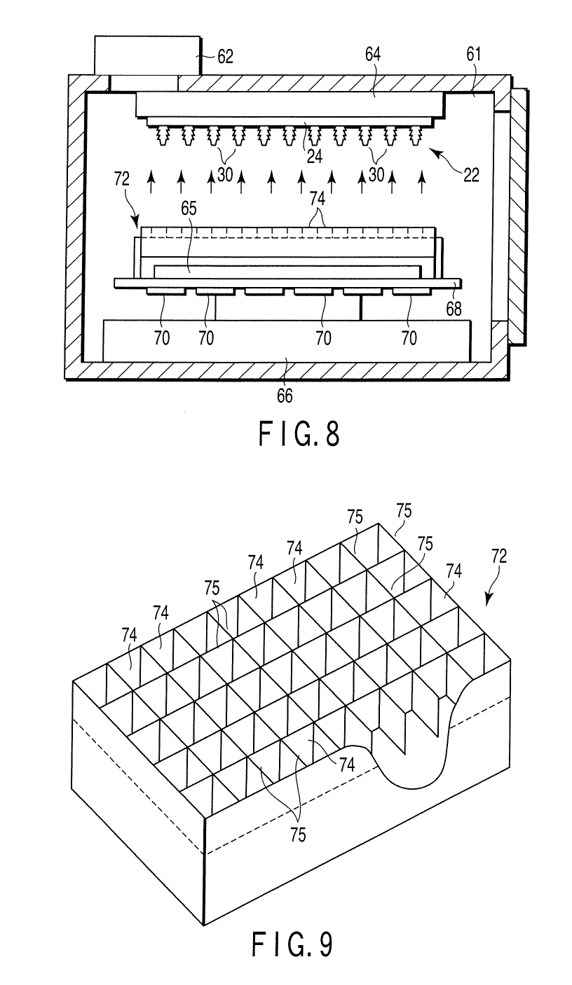

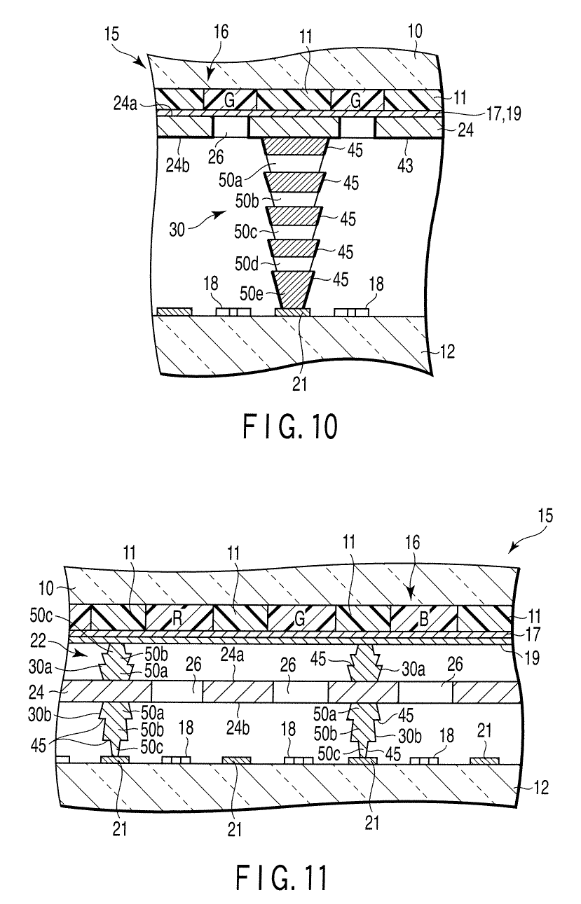

Subsequently, a metal oxide film, such as a film of chromium oxide, is formed on the supporting substrate 24 of the spacer structure 22 and the spacers 30 by a film forming apparatus. As shown in FIGS. 8 and 9, the film forming apparatus comprises a vacuum chamber 61 formed of a vacuum processing tank and a vacuum pump 62 that evacuates the vacuum chamber. A first conveyor mechanism 64 for supporting and conveying the spacer structure 22 is located in the vacuum chamber 61, and the supporting substrate 24 of the spacer structure 22 is supported by the first conveyor mechanism. Provided in the vacuum chamber 61 is a second conveyor mechanism 66, which conveys film sources 65 formed of chromium oxide to a predetermined position. The second conveyor mechanism 66 supports a support jig 68 for movement and height adjustment.

A plurality of film sources 65 are held on the support jig 68 and opposed to the spacer structure 22. Each film source 65 is formed in the shape of, e.g., an elongate rod and located parallel to the longitudinal direction of the spacer structure 22. The film sources 65 are arranged at predetermined spaces between them. A heating unit 70 for heating the film sources 65 is provided on the underside of the support jig 68. The heating unit 70 is constructed as a high-frequency heating system that can heat the film sources 65 in a non-contact manner, for example. It comprises a high-frequency coil and a high-frequency generator (not shown) that applies high frequencies to the heating coil. The heating unit 70 heats the film sources 65 through the support jig 68 from under the support jig. The support jig 68 is formed of a non-dielectric material, such as ceramic or glass, which cannot be influenced by high-frequency heating.

Provided on the support jig 68 is a grid 72, which functions as a guide member. As shown in FIGS. 8 and 9, the grid 72 is formed of a plate member in the shape of a square tube that has a plane dimension substantially equal to that of the supporting substrate 24 of the spacer structure 22. The grid 72 has a plurality of through holes 74, which extend parallel to one another, and a plurality of guide walls 75, which define the respective peripheral edges of the through holes and extend parallel to one another. The grid 72 overlies the film sources 65 so as to face the film sources 65 and the entire spacer structure 22 that is supported by the first conveyor mechanism 64. The through holes 74 of the grid 72 individually extend in the vertical direction and at right angles to the surface of the supporting substrate 24 of the spacer structure 22.

The following is a description of processes for forming the film of chromium oxide on the supporting substrate 24 of the spacer structure 22 and the spacers 30.

First, the spacer structure 22 is carried into the vacuum chamber 61 and supported by the first conveyor mechanism 64. In doing this, the spacer structure 22 is supported so that the supporting substrate 24 is situated substantially horizontally and that the spacers 30 extend downward.

Subsequently, the film sources 65 are set in a predetermined array on the upper surface of the support jig 68, and the grid 72 is located opposite these film sources. The support jig 68 is carried into the vacuum chamber 61 and located in a predetermined film forming position where it faces the spacer structure 22. The interior of the vacuum chamber 61 is previously kept at a high vacuum of about 10⁻⁵ Pa by means of the vacuum pump 62. Further, each film source 65 is previously heated to a given temperature lower than the evaporation temperature of the film source and degassed in advance.

After the film sources 65 are located in a vapor deposition position, chromium oxide for the film sources 65 is heated to a temperature not lower than its evaporation temperature by the high-frequency coil of the heating unit 70, whereby it is evaporated and scattered toward the spacer structure 22. The scattered chromium oxide passes through the through holes 74 of the grid 72 and is deposited successively on the respective outer surfaces of the spacers 30 and the second surface 24b of the supporting substrate 24 as objects of film formation by vacuum evaporation. As this is done, the scattering direction of the chromium oxide is defined by the grid 72 to be one predetermined direction that, in this case, is perpendicular to the second surface 24b of the supporting substrate 24, that is, the setup direction of each spacer 30. Each spacer 30 is shaped having a plurality of step portions. Thus, in the spacer 30, the film of chromium oxide is selectively formed on the surface of the fifth step portion 50e at its distal end and the opposite surfaces of the other step portions, while no film is formed on the respective outer circumferential surfaces of the first to fourth step portions 50a, 50b, 50c and 50d that are dead spaces as viewed in the scattering direction of the chromium oxide. Thus, the coating films 45 that are formed on the surface of the spacer 30 are formed intermittently in the extending direction of the spacer. In these processes, the films 43 and 45 of chromium oxide are formed in desired positions on the second surface 24b of the supporting substrate 24 and the outer surface of each spacer 30, respectively.

In the manufacture of the SED, the first substrate 10, which is provided with the phosphor screen 16 and the metal back 17, and the second substrate 12, which is provided with the electron emitting elements 18 and the wires 21 and joined with the sidewall 14, are prepared in advance.

Subsequently, the spacer structure 22 obtained in the aforesaid manner is temporarily attached to the first substrate 10 in a manner such that the first surface 24a of the supporting substrate 24 is in contact with the inner surface of the first substrate. In this state, the first substrate 10, the second substrate 12, and the spacer structure 22 are located in the vacuum chamber, the vacuum chamber is evacuated, and the first substrate is then joined to the second substrate with a sidewall 14 between them. Thus, the SED is manufactured having the spacer structure 22.

According to the SED constructed in this manner, each spacer 30 has a plurality of step portions arranged in its setup direction and the coating films 45 that are formed intermittently on the spacer surface and divided electrically from one another. Each coating film is formed of a material with a low secondary electron emission coefficient, e.g., a material that contains chromium oxide. Thus, the spacer surface can be prevented from undergoing secondary electron emission and electrification, so that electric discharge can be suppressed. Accordingly, the dielectric strength of the SED can be enhanced, and the reliability and display quality can be improved. Since the coating films 45 are formed intermittently and divided electrically from one another, a desired anode voltage can be applied to the first substrate without allowing the first substrate 10 and the second substrate 12 to connect electrically with each other through the spacers 30. At the same time, a current leakage through the spacers 30 can be restrained, so that the power consumption of the SED can be reduced.

According to the manufacturing method described, moreover, film formation in dead-angle regions with respect to one predetermined direction can be restrained by restricting the scattering direction of the film material to the one direction, so that the films can be easily distributed on the spacer surface.

Each spacer 30 is expected only to be shaped having dead-angle regions as viewed in the scattering direction of the film sources or having an angular distribution in the scattering direction, that is, it is not limited to the foregoing embodiment in configuration but may be formed having any other shape. According to a second embodiment shown in FIG. 10, each spacer 30 has five step portions 50a, 50b, 50c, 50d and 50d, first, second, third, fourth, and fifth, and is formed having a height of, for example, 1.4 mm. The adjacent step portions of the spacer 30 are formed so that the step portions on the proximal end side of the spacer are larger in diameter than the step portions on the distal end side of the spacer. The cross section of each step portion is elliptic, for example.

The first to fifth step portions 50a, 50b, 50c, 50d and 50e of the spacer 30 are tapered so that their respective diameters are reduced from the proximal end side of the spacer toward the distal end side. The proximal-end-side diameter of a distal-end-side step portion, out of each two adjacent step portions, is larger than the distal-end-side diameter of a proximal-end-side step portion. Thus, the first to fifth step portions 50a, 50b, 50c, 50d and 50e have their respective outer circumferential surfaces that are inclined with respect to the setup direction of the spacer, that is, to a direction perpendicular to a supporting substrate 24.

In the spacer 30, coating films 45 of a metal oxide, such as chromium oxide, copper oxide, or iron oxide that contains a material whose secondary electron emission coefficient ranges from 0.4 to 2.0, are formed to a desired thickness on the surface of the fifth step portion 50e at the distal end and the respective proximal-end-side peripheral surfaces of the other or first to fourth step portions 50a, 50b, 50c and 50d. The coating films 45 are not formed on the distal-end-side peripheral surface of each of the first to fourth step portions 50a, 50b, 50c and 50d, which is shadowed by the proximal end of a distal-end-side step portion with respect to the extending direction of the spacer. Thus, the coating films 45 that are formed on the surface of the spacer 30 are formed intermittently in the extending direction of the spacer and divided electrically from one another.

In the second embodiment, other configurations are the same as those of the foregoing first embodiment, so that like reference numerals are used to designate like portions, and a detailed description thereof is omitted. Further, an SED according to the second embodiment is manufactured by a manufacturing method identical to that of the foregoing embodiment. The same function and effect of the foregoing embodiment can be also obtained with the second embodiment.

Although the film of a metal oxide is formed as a coating film on the respective surfaces of the spacers 30 and the supporting substrate 24 according to the foregoing embodiment, it may be replaced with a metal film, such as a getter film. After a spacer structure is formed by the same processes of the foregoing embodiment, in this case, this spacer structure is tacked to a first substrate 10 in a manner such that a first surface of the supporting substrate 24 is in contact with the inner surface of the first substrate. Subsequently, the first substrate 10 is carried into the vacuum chamber 61 of the film forming apparatus and supported in a predetermined position by the first conveyor mechanism 64. In doing this, the first substrate 10 is located substantially horizontally, and the spacers 30 of the spacer structure 22 extend downward.

On the other hand, a getter material for film sources 65 and a grid 72 are set on the support jig 68 in the vacuum chamber 61. The getter material used may be a reactive getter obtained by depositing Ba by vacuum evaporation based on a thermal reaction between BaAl₄ powder and Ni powder, for example. The interior of the vacuum chamber 61 is previously kept at a high vacuum of about 10⁻⁵ Pa by means of the vacuum pump 62. The getter material is previously heated to a given temperature lower than its evaporation temperature and degassed in advance.

Subsequently, the getter material is heated to a temperature not lower than its evaporation temperature by the heating unit 70, whereby it is evaporated and scattered toward the spacer structure 22. The scattered getter material passes through through holes 74 of the grid 72 and is deposited successively on the respective outer surfaces of the spacers 30 and a second surface 24b of the supporting substrate 24 by vacuum evaporation. As this is done, the scattering direction of the getter material is defined by the grid 72 to a direction perpendicular to the second surface 24b of the supporting substrate 24, that is, the setup direction of each spacer 30. Thereupon, getter films are formed individually in desired positions on the entire second surface 24b of the supporting substrate 24 and the outer surface of each spacer 30.

After the film formation, the first substrate 10 and the spacer structure 22 are delivered to another vacuum chamber without being exposed to the atmosphere and are sealed to the second substrate 12 in a vacuum atmosphere. Thereupon, the SED is obtained. The same function and effect of the foregoing embodiment can be also obtained with the SED constructed in this manner.

Although the spacers 30 are set up integrally on one surface of the supporting substrate 24 in the foregoing embodiment, they may alternatively be set up on the inner surface of the first substrate or the second substrate. As in a third embodiment shown in FIG. 11, moreover, a spacer structure 22 may be provided with a supporting substrate 24 and first and second spacers that are set up individually integrally on the opposite sides of the supporting substrate. Specifically, the spacer structure 22 is interposed between a first substrate 10 and a second substrate 12. The supporting substrate 24 has a first surface 24a opposed to the inner surface of the first substrate 10 and a second surface 24b opposed to the inner surface of the second substrate 12, and is located parallel to these substrates. A large number of electron beam apertures 26 are formed in the supporting substrate 24 by etching or the like. The electron beam apertures 26 are arrayed opposite electron emitting elements 18, individually, and are permeated by electron beams emitted from the electron emitting elements.

The supporting substrate 24 is formed of a plate of, for example, an iron-nickel-based metal with a thickness of 0.1 to 0.3 mm. The surfaces of the supporting substrate 24 are covered by an oxide film of elements that constitute the metal plate, e.g., an oxide film of Fe₃O₄ or NiFe₂O₄. The surfaces 24a and 24b of the supporting substrate 24 and the respective wall surfaces of the electron beam apertures 26 are covered by a high-resistance film that has a discharge current limiting effect. This high-resistance film is formed of a high-resistance substance that consists mainly of glass.

First spacers 30a are set up integrally on the first surface 24a of the supporting substrate 24 and situated between the adjacent electron beam apertures 26. The respective distal ends of the first spacers 30a abut against the inner surface of the first substrate 10 through a getter film 19, a metal back 17, and light shielding layers 11 of a phosphor screen 16. Second spacers 30b are set up integrally on the second surface 24b of the supporting substrate 24 and situated between the adjacent electron beam apertures 26. The respective distal ends of the second spacers 30b abut against the inner surface of the second substrate 12. In this case, the distal ends of the second spacers 30b are situated individually on wires 21 that are provided on the inner surface of the second substrate 12. The first and second spacers 30a and 30b are situated in alignment with one another and are formed integrally with the supporting substrate 24 in a manner such that the supporting substrate 24 is held between them from both sides.

Each first spacer 30a is tapered so that its diameter is reduced from the side of the supporting substrate 24 toward its extended end. Each spacer 30 has the plurality of step portions that are stacked in layers from its proximal end on the side of the supporting substrate 24 toward the extended end, and is formed as an irregular-surfaced spacer. In the present embodiment, each first spacer 30a has three step portions 50a, 50b and 50c, first, second, and third, and is formed having a height of, for example, 0.75 mm. The adjacent step portions of the first spacer 30a are formed so that the step portions on the proximal end side of the spacer are larger in diameter than the step portions on the distal end side of the spacer. The cross section of each step portion is elliptic, for example.

The first and second step portions 50a and 50b of the first spacer 30a are tapered so that their respective diameters increase from the proximal end side of the spacer toward the distal end side. The proximal-end-side diameter of a distal-end-side step portion, out of each two adjacent step portions, is smaller than the distal-end-side diameter of a proximal-end-side step portion. Each of the first and second step portions 50a and 50b has an annular opposite surface that faces the first substrate 10 in substantially parallel relation. The third step portion 50c that is situated at the distal end of each first spacer 30a is tapered from its proximal end side toward the distal end side. The first, second, and third step portions 50a, 50b and 50c have their respective outer circumferential surfaces that are inclined with respect to the setup direction of the spacer, that is, to a direction perpendicular to the supporting substrate 24.

In the first spacer 30a thus having a plurality of step portions, coating films 45 of a metal oxide, such as chromium oxide, copper oxide, or iron oxide that contains a material whose secondary electron emission coefficient ranges from 0.4 to 2.0, are formed to a desired thickness on the surface of the third step portion 50c at the distal end and the respective distal-end-side surfaces of the first and second step portions or, in this case, the respective opposite surfaces of the step portions. The coating films 45 are not formed on the respective outer circumferential surfaces of the first and second step portions 50a and 50b. Thus, the coating films 45 that are formed on the surface of the first spacer 30a are formed intermittently in the extending direction of the spacer and divided electrically from one another.

Each second spacer 30b is formed in the same manner as the first spacer and has first to third step portions and coating films 45.

The spacer structure 22 constructed in this manner is located between the first substrate 10 and the second substrate 12. The first and second spacers 30a and 30b abut against the respective inner surfaces of the first substrate 10 and the second substrate 12, thereby supporting an atmospheric load that acts on these substrates and keeping the space between the substrates at a predetermined value.

In the third embodiment, other configurations are the same as those of the foregoing first embodiment, so that like reference numerals are used to designate like portions, and a detailed description thereof is omitted. The SED according to the third embodiment and its spacer structure 22 can be manufactured by a manufacturing method identical to the manufacturing method according to the foregoing first embodiment. The same function and effect of the foregoing first embodiment can be also obtained with the third embodiment.

The present invention is not limited directly to the embodiments described above, and its components may be embodied in modified forms without departing from the spirit of the invention. Further, various inventions may be made by suitably combining a plurality of components described in connection with the foregoing embodiments. For example, some of the components according to the embodiments may be omitted. Furthermore, components according to different embodiments may be combined as required.

In the foregoing embodiments, the spacers are formed on the supporting substrate. Alternatively, however, the supporting substrate may be omitted with the spacers provided directly on the inner surface of the first substrate. The diameter, height, and number of steps of the spacers and the dimensions, materials, etc. of the other components are not limited to the foregoing embodiments, but may be suitably selected as required. Although vacuum evaporation is used as the film forming method according to the foregoing embodiments, sputtering or any other method may be used instead. This invention is not limited to image display devices that use surface-conduction electron emitting elements as electron sources, but may be also applied to image display devices that use other electron sources, such as the field-emission type, carbon nanotubes, etc.

What is claimed is:

1. An image display device comprising:
an envelope having a first substrate and a second substrate located opposite the first substrate across a gap;
a plurality of pixels provided in the envelope; and
a plurality of columnar spacers which are individually formed of a dielectric material, are arranged between the first substrate and the second substrate in the envelope, and support an atmospheric load acting on the first and second substrates,
each of the spacers having a plurality of step portions arranged in a setup direction thereof and coating films which are formed intermittently on a surface of the spacer and divided electrically from one another.

2. The image display device according to claim 1, wherein the coating films of each spacer are formed of metal oxide films containing a material whose secondary electron emission coefficient ranges from 0.4 to 2.0.

3. The image display device according to claim 1, wherein each of the spacers has a proximal end and a distal end, and adjacent step portions of the spacer are formed so that the step portions on the proximal end side are larger in diameter than the step portions on the distal end side.

4. The image display device according to claim 3, wherein all the step portions of each of the spacers except the step portion at the distal end are formed so that diameter increases from the proximal end side of the spacer toward the distal end side and a proximal-end-side diameter of a distal-end-side step portion, out of each two adjacent step portions, is smaller than a distal-end-side diameter of a proximal-end-side step portion.

5. The image display device according to claim 4, wherein the coating films are formed on an outer circumferential surface of a step portion situated at the distal end of the spacer and respective distal-end-side surfaces of the other step portions.

6. The image display device according to claim 3, wherein the step portions of each of the spacers are formed so that the diameter is reduced from the proximal end side of the spacer toward the distal end side and a proximal-end-side diameter of a distal-end-side step portion, out of each two adjacent step portions, is larger than a distal-end-side diameter of a proximal-end-side step portion.

7. The image display device according to claim 6, wherein the coating films are formed on an outer circumferential surface of a step portion situated at the distal end of the spacer and respective proximal-end-side surfaces of the other step portions.

8. The image display device according to claim 1, which comprises a supporting substrate opposed to the first and second substrates and having a plurality of electron beam apertures opposed individually to the electron emission sources, and wherein the plurality of spacers are set up on at least one surface of the supporting substrate.

9. The image display device according to claim 8, wherein the supporting substrate has a first surface in contact with the first substrate and a second surface opposed to the second substrate, and the plurality of spacers are set up on the second surface.

10. The image display device according to claim 1, which comprises a supporting substrate located between the first substrate and the second substrate and having a first surface opposed to the first substrate and a second surface opposed to the second substrate, and wherein the spacers include a plurality of first spacers set up on the first surface and a plurality of second spacers set up on the second surface, the first and/or second spacers having the plurality of step portions and the coating films formed intermittently on the spacer surface and divided electrically from one another.

11. A method of manufacturing an image display device which comprises an envelope having a first substrate and a second substrate located opposite the first substrate across a gap, a plurality of pixels provided in the envelope, and a plurality of columnar spacers which are individually formed of a dielectric material, are set up between the first substrate and the second substrate in the envelope, and support an atmospheric load acting on the first and second substrates, each of the spacers having a plurality of step portions arranged in a setup direction thereof and coating films are formed intermittently on a surface of the spacer and divided electrically from one another, the method comprising:
forming a plurality of columnar spacers each having a plurality of step portions arranged in the setup direction, using the dielectric material; and
scattering a film material toward the spacers in a vacuum atmosphere to form the coating films on the spacer surface and, at the same time, regulating the direction of scattering of the film material in one predetermined direction to control a film distribution by a guide member, thereby forming the coating films formed intermittently on the spacer surface and divided electrically from one another.

12. The method of manufacturing an image display device according to claim 11, wherein the one predetermined direction is regulated to a direction parallel to the setup direction of the spacers.

13. The method of manufacturing an image display device according to claim 11, which comprises preparing a supporting substrate having a plurality of beam apertures formed therein, forming the plurality of spacers on a surface of the supporting substrate, then scattering the film material toward the surface of the supporting substrate and the spacers, thereby forming the coating films on the surface of the supporting substrate and the surface of each spacer.

14. The method of manufacturing an image display device according to claim 11, wherein the coating films are formed by scattering a metal which contains a material whose secondary electron emission coefficient ranges from 0.4 to 2.0.

15. The method of manufacturing an image display device according to claim 11, which comprises forming a molding die having a plurality of spacer forming holes and a plurality of hole forming portions which are situated individually around the spacer forming holes, define the spacer forming holes having first and second step portions, and are formed of an elastically deformable ultraviolet transmitting material, loading each spacer forming hole of the molding die with an ultraviolet-curing spacer forming material, applying ultraviolet rays to the spacer forming material through the molding die, thereby curing the spacer forming material, and releasing the molding die while elastically deforming the hole forming portions, thereby forming the spacers.

16. The method of manufacturing method an image display device according to claim 15, wherein the spacer forming material is a glass paste containing at least an ultraviolet-curing binder and a glass filler.

17. The method of manufacturing an image display device according to claim 11, wherein the guide member is a grid having a plurality of through holes through which the film material passes and a plurality of guide walls which define respective peripheral edges of the through holes and extend in the one predetermined direction.
